(19) United States
(12) Patent Application Publication
(10) Pub. No.: US 2018/0331247 A1
(43) Pub. Date: Nov. 15, 2018

(54) SOLAR CELL PEPARATION METHOD

(71) Applicant: GWANGJU INSTITUTE OF SCIENCE AND TECHNOLOGY, Buk-gu, Gwangju (KR)

(72) Inventors: Jongho LEE, Buk-gu, Gwangju (KR); Juho KIM, Buk-gu, Gwangju (KR)

(73) Assignee: GWANGJU INSTITUTE OF SCIENCE AND TECHNOLOGY, Buk-gu, Gwangju (KR)

(21) Appl. No.: 15/775,923

(22) PCT Filed: Nov. 11, 2016
(86) PCT No.: PCT/KR2016/013047

§ 371 Date: May 14, 2018

(30) Foreign Application Priority Data
Nov. 13, 2015 (KR) 10-2015-0159802

(51) Int. Cl. H01L 31/18; H01L 31/0224; H01L 31/0236; H01L 31/0392; H01L 31/05

(52) U.S. Cl. CPC H01L 31/18; H01L 31/022425; H01L 31/05; H01L 31/03926; H01L 31/0236

(57) ABSTRACT

A method for fabricating a solar cell according to the present invention includes steps of forming a sacrificial layer pattern on a substrate and a solar cell layer on the sacrificial layer pattern, patterning photoresist covering the solar cell layer through a photolithography process, attaching the solar cell layer by using a stamp having adhesion force and separating the solar cell layer from the substrate so that the photoresist remains between the solar cell layer and the stamp and on a side surface of the solar cell layer, preparing a flexible substrate on which a metal layer is deposited, welding the stamp, to which the solar cell layer is attached, to the flexible substrate, melting the photoresist formed between the solar cell layer and the stamp and the photoresist formed on the side surface of the solar cell layer, and separating the stamp from the substrate.

### TECHNICAL FIELD

The present invention relates to a method for fabricating solar cells, and more particularly, to a method for fabricating vertical type compound semiconductor solar cells through a transfer method of separating a compound semiconductor from a substrate.

### BACKGROUND ART

Solar cell semiconductor devices are drawing attention as alternative energy sources due to the depletion of fossil fuels such as petroleum. Such a solar cell is a device that is driven only by irradiating light. It is expected to be a representative example of green energy because it does not require additional energy for driving and there is no unnecessary environmental pollutant generated during the driving. In addition, the solar cell is attracting attention as an energy source that supplies energy to areas where establishment of power plants are difficult because of relatively small geographical limitations.

A technique for separating a compound semiconductor from a substrate in a process of fabricating a solar cell semiconductor device has become an issue. Recently, transfer printing process technologies have been actively researched.

In the fabrication of the solar cells using a general transfer printing process, electronic devices such as solar cells, LEDs, and photodetectors are epitaxially grown on the substrate, and semiconductor processes such as an etching process, a deposition process, and the like are performed to fabricate micro-sized devices.

Also, in order to remove and separate a sacrificial layer from the substrate, photoresist is patterned in the form of an anchor that holds devices by using a photolithography process. Also, if necessary, a process of completely covering the micro devices with the photoresist is performed to prevent the devices from being damaged by an etchant.

In addition, the devices are attached and detached by using an elastomeric stamp having a sticky property such as polydimethylsiloxane (PDMS), ecoflex, and the like. A transfer printing process is completely performed on a flexible substrate having a flexible property by using an adhesive.

However, since the adhesive used for the transfer onto the flexible substrate is an insulation material, electricity is not allowed to pass between upper and lower portions. As a result, it is impossible to form an electrode on a bottom surface of the micro device.

A solar cell having a vertical structure is more advantageous in terms of shot circuit current, an open circuit voltage, and a size of an active area than a solar cell having a lateral structure. The vertical structure may not be used in fabricating a thin film solar cell using the transfer printing process due to the problem of the adhesive in the transfer printing process.

In addition, in the process of forming a bottom electrode facing a top surface, when the bottom electrode is formed to have a thin thickness, it may be difficult to perform an etch stop in a bottom contact layer, and the bottom electrode may be broken during to the transfer printing. Thus, there is a problem that the bottom contact layer becomes thick. When the bottom contact layer is formed to have the thick thickness, fabricating costs increase, and strain increases in proportion to the thickness to deteriorate the flexibility of the fabricated solar cell device.

### DISCLOSURE OF THE INVENTION

### Technical Problem

An object of this embodiment is to provide a method for fabricating a solar cell, through which a micro device is capable of being stably transferred without using an adhesive between the micro device and a flexible substrate.

### Technical Solution

A method for fabricating a solar cell according to an embodiment includes steps of: forming a sacrificial layer pattern on a substrate and a solar cell layer on the sacrificial layer pattern; patterning photoresist covering the solar cell layer through a photolithography process; attaching the solar cell layer by using a stamp having adhesion force and separating the solar cell layer from the substrate so that the photoresist remains between the solar cell layer and the stamp and on a side surface of the solar cell layer; preparing a flexible substrate on which a metal layer is deposited; welding the stamp, to which the solar cell layer is attached, to the flexible substrate; melting the photoresist formed between the solar cell layer and the stamp and the photoresist formed on the side surface of the solar cell layer; and separating the stamp from the substrate.

Also, the step of forming the solar cell layer having a predetermined pattern on the substrate may include steps of: preparing a substrate including a sacrificial layer to pattern the sacrificial layer, thereby forming the solar cell layer and a top electrode on a top surface of the substrate; and patterning the sacrificial layer so that the patterned sacrificial layer has a surface area greater than that of the solar cell layer.

Also, the method may further include, after the step of patterning the photoresist covering the solar cell layer through the photolithography process, a step of performing an undercut process for selectively removing only the sacrificial layer.

The method may further include, after the step of separating the solar cell layer from the substrate, a step of forming a mask on a lower portion of the solar cell layer to form a bottom electrode on a bottom surface of the solar cell layer.

Also, in the step of separating the solar cell layer from the substrate, a top surface and the side surface of the solar cell layer may be attached to the stamp and separated from the substrate in a state of being surrounded by the photoresist.

Also, the solar cell layer may be patterned into a plurality of square shapes, and a top electrode having a bar shape may be patterned on a top surface of the solar cell layer.

Also, in the stamp of welding the stamp, to which the solar cell layer is attached, to the flexible substrate, the solar cell layer may be disposed between the stamp and the flexible substrate, and air remaining between the substrate and the stamp may be removed.

Also, in the step of melting the photoresist surrounding the solar cell layer, a pressure of 80 kPa and heat having a temperature of 170 degrees may be applied to the photoresist to allow the photoresist to cover a top surface and the side surface of the solar cell layer.

Also, in the step of melting the photoresist surrounding the solar cell layer, a cold-welding process may be performed so that the metal layer disposed on a top surface of the flexible substrate to a bottom surface of the solar cell.

Also, the stamp may include a film stamp having a triple structure, which is formed by performing spin coating on one selected from a polyimide (PI) film, polyethylene, polyethylene terephthalate (PET), and polyester by using an elastomeric solution on an elastomeric stamp having adhesion force to adhere again to the other elastomeric stamp.

Also, the method may further include, after the solar cell layer is transferred onto the flexible substrate, a step of forming an electrical connection structure between the solar cell layers.

### Advantageous Effects

The method for fabricating the solar cell according to the present invention may have advantages in that the device is transferred to the flexible substrate without using the adhesive in the transfer printing process of separating the semiconductor device from the semiconductor substrate, thereby fabricating the vertical-type solar cell.

In the method for fabricating the solar cell according to the present invention, since the transfer printing process is performed after separating the epitaxially grown compound semiconductor solar cell from the compound semiconductor substrate having the relatively high unit price, the substrate may be recycled, and the separated thin film-type devices may be used for fabricating the flexible electronic devices.

### BRIEF DESCRIPTION OF THE DRAWINGS

FIGS. 1 to 6 are views illustrating a process of preparing a micro device sample to be transferred in a method for fabricating a solar cell according to an embodiment.

FIGS. 7 to 9 are views illustrating a process of transferring a device onto a flexible substrate in the method for fabricating the solar cell according to an embodiment.

FIGS. 10 to 12 are views illustrating a process of forming an electrical connection structure between the transferred devices in the method for fabricating the solar cell according to an embodiment.

### MODE FOR CARRYING OUT THE INVENTION

Although embodiments are described in detail with reference to the accompanying drawings, the present invention is not limited to the embodiments. Moreover, detailed descriptions related to well-known functions or configurations will be ruled out in order not to unnecessarily obscure subject matters of the present invention.

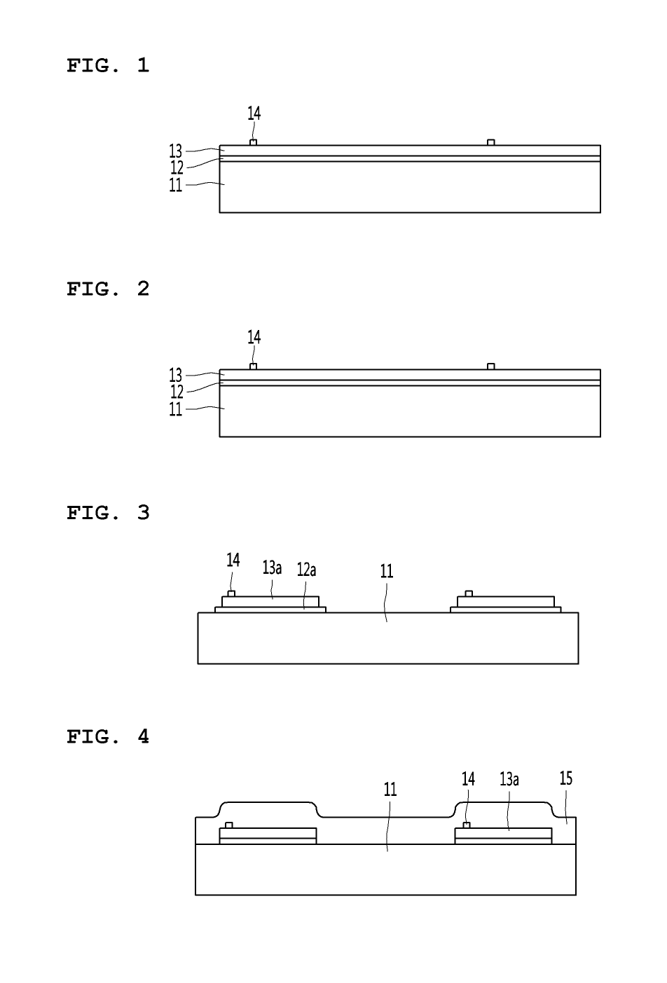

FIGS. 1 to 6 are views illustrating a process of preparing a micro device sample to be transferred in a method for fabricating a solar cell according to an embodiment. A process of preparing a micro device sample to be transferred may include a step of preparing a substrate including a sacrificial layer to pattern a solar cell layer and a top electrode on a top surface, a step of patterning the sacrificial layer so that the sacrificial layer has a surface area greater than that of the solar cell layer, a step of applying photoresist to an upper portion of the substrate and performing an undercut process on the sacrificial layer, a step of attaching a film stamp to the photoresist and detaching the solar cell layer, and a step of forming a mask below the solar cell layer to form a bottom electrode.

Sequentially, the above-described steps will be described with reference to the accompanying drawings.

First, referring to FIG. 1, a solar cell device layer 13 including a sacrificial layer 12 may be grown on a compound semiconductor substrate (hereinafter, referred to as a substrate 11) through an epitaxial process. The compound semiconductor substrate may be a GaAs wafer, and the solar cell device may also be made of GaAs.

Also, although not shown, an n-contact layer may be formed on a top surface of the solar cell device layer 13. Ti and Au are applied to a top surface of the n-contact layer through E-beam evaporation, and photoresist is patterned by using a photolithography process.

When wet etching is performed by using an Au etchant (TFA) and HF, the Ti and Au on a portion on which the photoresist does not exist may be removed to form a top electrode 14 having a bar shape. Sequentially, the n-contact layer is selectively wet-etched using a solution in which a critic acid and hydrogen peroxide (H₂O₂) are mixed with each other.

Referring to FIG. 2, the remaining photoresist is cleaned using acetone and isopropyl alcohol (IPA), and then, the photolithography process is performed again to pattern the photoresist for forming an active area of the solar cell device layer 13. The photoresist may be formed to have a plurality of square-shaped patterns. When the wet etching is performed on the photoresist by using an etching solution in which H₃PO₄, H₂O₂, and H₂O are mixed with each other, a plurality of solar cell layer 13a may be formed on the sacrificial layer 12.

Referring to FIG. 3, the photoresist for patterning the solar cell layers 13a, and then, the photoresist process is performed again to form photoresist having a square shape that is larger than each of the solar cell layers 13a, which is the active area of the solar cell device layer 13. When the wet etching is performed on the photoresist by using a hydrochloric acid (HCl), the sacrificial layer is formed into a sacrificial layer pattern 12a having a square shape that is lager than each of the solar cell layers 13a.

Referring to FIG. 4, spin coating is performed on the photoresist so that a portion of the sacrificial layer pattern 12a is exposed while completely covering the solar cell layers 13a as a step of selectively etching only the sacrificial layer pattern 12a. In order to expose the sacrificial layer pattern 12a, a plurality of holes may be formed in a circumference of an area corresponding to an upper portion of an edge of the sacrificial layer.

Sequentially, when an undercut process is performed for about four hours by using a solution in which a hydrochloric acid (HCl) and water are mixed with each other, the solution may be introduced into the plurality of holes to selectively etch only the sacrificial layer pattern 12a. In this process, the photoresist may serve to hole the solar cell layer 13a so that the solar cell layer does not sink due to the removal of the sacrificial layer pattern 12a.

Referring to FIG. 5, after the undercut process is completed, a film stamp 16 is attached to an upper portion of the photoresist 15 to separate only the solar cell layer 13a.

The stamp may be fabricated in the form of a film having a triple structure, which is formed by performing spin coating on one selected from a polyimide (PI) film, polyethylene, polyethylene terephthalate (PET), and polyester by using an elastomeric solution on an elastomeric stamp having adhesion force to adhere again to the other elastomeric stamp. A PDMS stamp may be used as the elastomeric stamp.

The film stamp 16 may be fabricated by performing the spin coating one selected from a polyimide (PI) film, polyethylene, polyethylene terephthalate (PET), and polyester by using polydimethylsiloxane (PDMS) or an elastomeric to adhere again to the elastomeric stamp having the adhesion force.

The polyimide (PI) film having low thermal strain may be attached to the film stamp 16 to prevent the elastomeric stamp such as the polydimethylsiloxane (PDMS) from being deformed and also prevent the elastomeric stamp from being deformed by heat or a pressure.

The film stamp 16 is placed on the photoresist 15 formed on the solar cell layer 13a on which the undercut is completed and then waits until the film stamp completely adheres to the photoresist 15 and the PDMS provided in the film stamp 16. After the film stamp completely adheres, when the film stamp 16 is detached upward, the solar cell layers 13a are separated. In the above-described separation process, upper photoresist 15a is disposed on the solar cell layer 13a, and lateral photoresist 15b surrounding side surfaces of the solar cell layer 13a and the upper photoresist 15a remains.

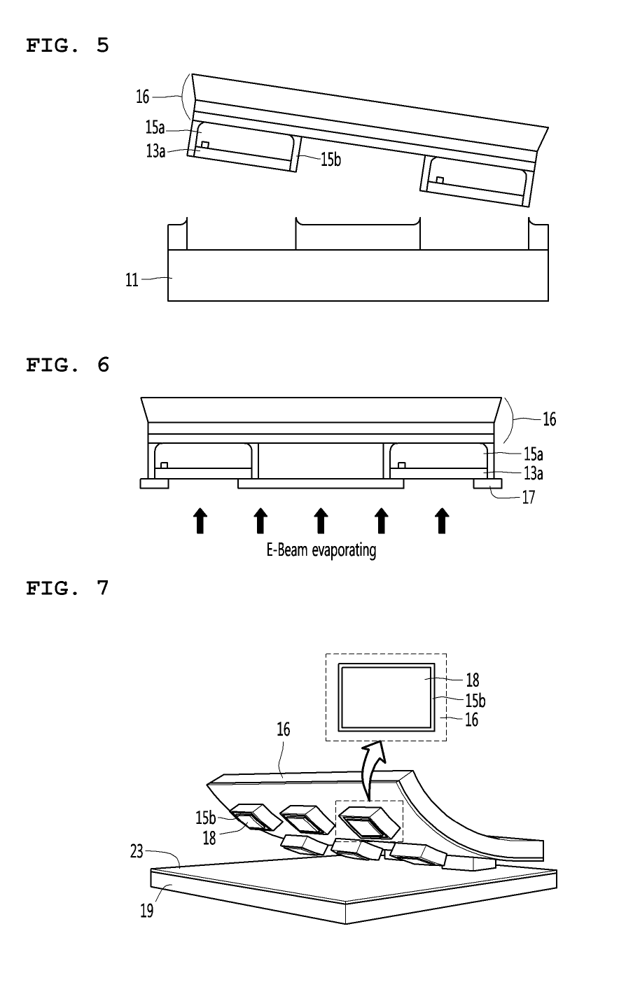

Referring to FIG. 6, a shadow mask that exposes a portion of a bottom surface of the solar cell layer 13a is deposited, and a bottom electrode that functions as a back reflector is selectively deposited by using E-beam evaporation. The bottom surface of the solar cell layer 13a may be a p-contact layer. When the above-described processes are performed, the deposition of the bottom electrode on the bottom surface of the solar cell layer 13a is completed, and then, when the film stamp is detached from the PDMS stamp, the preparation of the solar cell layer 13a to be transferred onto the flexible substrate may be completed.

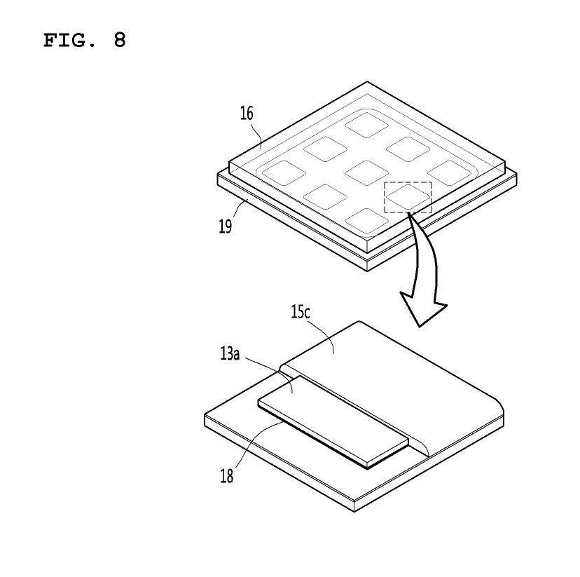

FIGS. 7 to 9 are views illustrating a process of transferring a device onto the flexible substrate in the method for fabricating the solar cell according to an embodiment. The process of transferring the device onto the flexible substrate may include a step of preparing a flexible substrate on which a metal layer is deposited, a step of welding a film stamp, to which the solar cell layer is attached, to the substrate, a step of melting the photoresist surrounding the solar cell layer, and a step of detaching the film stamp from the substrate. Sequentially, the steps will be described in detail with reference to the accompanying drawings.

Referring to FIG. 7, a flexible substrate 19 having flexibility may be prepared, and a metal layer 23 that functions as an electrode may be deposited on the flexible substrate 19.

When the film stamp 16 fabricated in FIG. 6 comes into contact with a top surface of the metal layer 23, the bottom electrode 18 deposited on the bottom surface of the solar cell layer 13a and the metal layer 23 come into contact with each other due to the adhesion force with the PDMS stamp provided in the film stamp 16. In this state, the PDMS stamp disposed around the solar cell layer 13a and the metal layer 23 may stably adhere to each other. In order to enhance the adhesion force, it is preferable to use a vacuum machine so as to maximally remove internal air.

In FIG. 7, when the square area including the solar cell layer 13a is viewed from the bottom, it is seen that the bottom electrode 18 is deposited on a central portion of the square shape of the solar cell layer 13a, the lateral photoresist 15b is disposed along a circumference of the central portion, and the PDMS stamp is disposed around the lateral photoresist 15b.

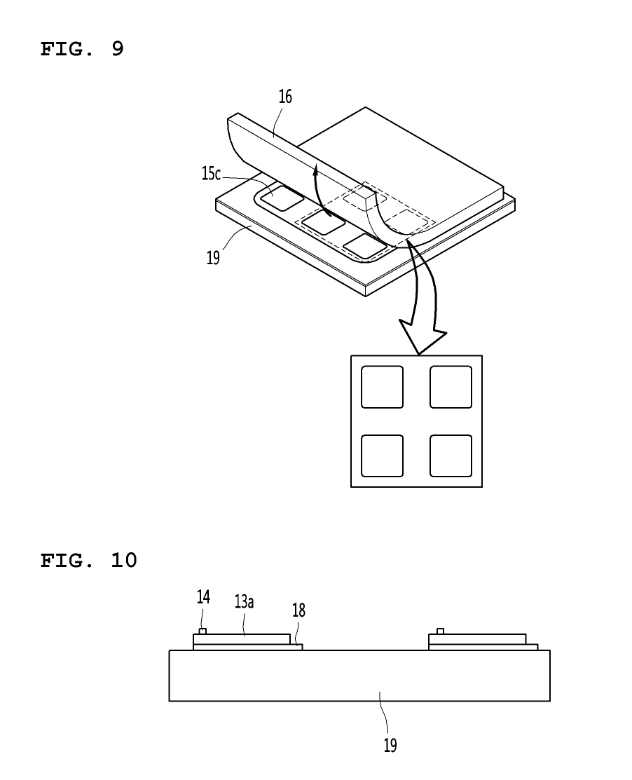

Referring to FIG. 8, the air remaining between the substrate 19 and the PDMS stamp is removed, and a pressure of about 80 kPa and heat having a temperature of 170 degrees are applied to melt the upper photoresist 15a and the lateral photoresist 15b, which cover the top surface and the side surface of the solar cell layer 13a, and simultaneously, to perform cold-welding.

A portion expressed as an arrow in FIG. 8 shows a state after the upper photoresist 15a and the lateral photoresist 15b are melted. When the cold-welding is performed, the bottom electrode 18 disposed on the solar cell layer 13a and the metal layer 23 of the flexible substrate may be welded to each other. Thus, since the adhesion force between the two metals for completing the transfer through only the cold-welding is too less, when the stamp is removed, the solar cell layer 13a may be shaken or detached.

In an embodiment, the upper photoresist 15a and the lateral photoresist 15b, which remain during the undercut process, are used as complementary members for the adhesion. That is, an additional adhesion layer is not disposed between the solar cell layer 13a and the flexible substrate 19, but the photoresist is used as a means for covering the solar cell layer 13a. When the upper photoresist 15a and the lateral photoresist 15b are melted by the heat, the upper photoresist 15a and the lateral photoresist 15b may be bundled together as one photoresist 15c, and the photoresist may adhere to the flexible substrate 19, and simultaneously, cover the solar cell layer 13a to complement the process of transferring the solar cell layer 13a onto the substrate.

Sequentially, as illustrated in FIG. 9, when the film stamp 16 is peeled off upward, the solar cell layer 13a disposed on the film stamp 16 is transferred onto the substrate 19, and then, the film stamp 16 is removed. When viewed from the upper side in FIG. 9, the solar cell layer 13a constituted by the plurality of square shapes are disposed, and the photoresist 15c covers the solar cell layer 13a. When the photoresist 15c is cleaned by using acetone and IPA, the process of transferring the solar cell layer 13a onto the flexible substrate may be completed.

According to the present invention, since the photoresist 15c fixes the solar cell layer 13a, the solar cell layer 13a may be stably transferred through only the process of melting the photoresist and peeling off the film stamp without previously performing the cold-welding.

However, in an embodiment, after the photoresist 15c is removed, since only van der Waals force is applied between the solar cell layer 13a and the flexible substrate, it is preferable that the cold-welding is performed because there is a possibility that the solar cell layer 13a is separated in a subsequent process.

FIGS. 10 to 13 are views illustrating a process of forming an electrical connection structure between the transferred devices in the method for fabricating the solar cell according to an embodiment. A process of forming an electrical connection structure between the transferred devices may include a step of patterning the metal layer on the flexible substrate to form an electrode pattern, a step of applying the photoresist to cover the solar cell layer disposed on the flexible substrate, a step of forming a hole so that portions of the top electrode disposed on the upper portion of the solar cell layer and the electrode pattern disposed on the lower portion of the solar cell layer are exposed, and a step of forming a metal line to electrically connect the electrode pattern of the adjacent solar cell layer to the top electrode. Sequentially, each of the processes will be described in detail with reference to the accompanying drawings.

Referring to FIG. 10, the photoresist on the metal layer 23 disposed on the flexible substrate 19 may be patterned through the photolithography process, and Au and Ti forming the metal layer may be wet-etched by using an Au etchant and HF to form the electrode pattern 18.

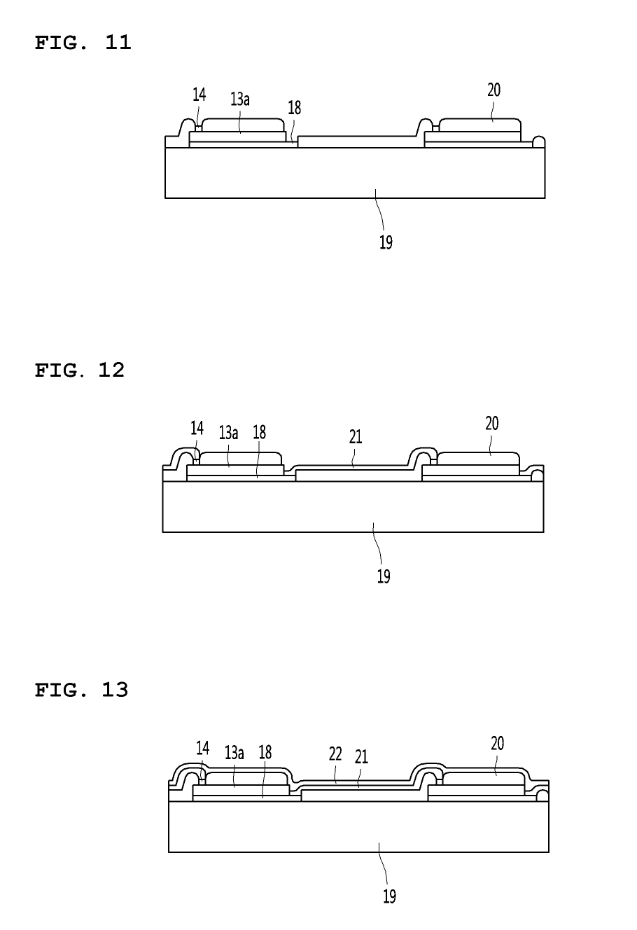

Referring to FIG. 11, epoxy-based photoresist 20 such as SU-8 is spin coated onto the flexible substrate 19. Here, the spin coating may be performed so that portions of the top electrode 14 and the electrode pattern 18 are exposed. Sequentially, the photolithography process including a soft bake step, an exposure step, and a post exposure bake (PEB) step may be performed at a temperature of 85 degrees to enhance fixing force of the solar cell layer 13a.

Referring to FIG. 12, a metal lift off process is performed to electrically connect the solar cell layers 13a to each other in series. In the metal lift off process, the metal line 21 may be deposited on the photoresist 20 covering the solar cell layers 13a. Here, the metal line 21 may be deposited to connect the electrode pattern 18 exposed between the adjacent solar cell layers 13a to the exposed top electrode 14.

It is preferable that negative photoresist is used as the photoresist 20 because a pattern generated when the negative photoresist is used is more suitable for the lift off process than positive photoresist. The spin coating at a speed of 3,000 rpm, the heating at a temperature of 110° C., the exposure, and the heating at a temperature of 110° C. are performed to form the metal line 21 for the lift off process. The metal line may be deposited using a sputter system. After the deposition is completed, since the deposited metal line is put into acetone and then lifted off, the unnecessary metal may be lifted off.

Referring to FIG. 13, a process of applying a protection film may be performed to protect the metal line 21 of the solar cell layer 13a. The protection film may be made of epoxy-based photoresist such as SU-8. When the above-described processes are performed, the solar cell device having a vertical structure may be finally fabricated.

Electrical properties of the solar cell having the vertical structure, which is fabricated through the methods according to an embodiment, and the solar cell having the lateral structure according to the related art were compared with each other.

In the solar cell according to an embodiment, short circuit current density was measured to be 19.4 mA/cm², and photoelectric efficiency was measured to be 15.2%. In the lateral-type solar cell according to the related art, short circuit current density was measured to be 17.9 mA/cm², and photoelectric efficiency was measured to be 14%.

It may be determined that the short circuit current density and the photoelectric efficiency increase by light reflected by the back reflector provided in the vertical structure even though the thickness of the solar cell according to an embodiment is reduced.

As described above, in the method for fabricating the solar cell according to an embodiment, since the transfer method in which the adhesive is not used in the transfer process of detaching the semiconductor device from the semiconductor substrate is applied, the vertical-type solar cell having the improved short circuit current density and photoelectric efficiency may be fabricated. In addition, the thin film-shaped devices that are separated through the method for fabricating the solar cell according to an embodiment may be transferred onto the flexible substrate to fabricate the flexible electronic equipment having excellent characteristics.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

### INDUSTRIAL APPLICABILITY

The method for fabricating the solar cell according to the present invention may have an advantageous effect in fabricating the vertical-type solar cell, and also, since the transfer printing process is performed after separating the epitaxially grown compound semiconductor solar cell from the compound semiconductor substrate having the relatively high unit price, the substrate may be recycled, and the separated thin film-type devices may be used for fabricating the flexible electronic devices.

1. A method for fabricating a solar cell, the method comprising steps of:
forming a sacrificial layer pattern on a substrate and a solar cell layer on the sacrificial layer pattern;
patterning photoresist covering the solar cell layer through a photolithography process;
attaching the solar cell layer by using a stamp having adhesion force and separating the solar cell layer from the substrate so that the photoresist remains between the solar cell layer and the stamp and on a side surface of the solar cell layer;
preparing a flexible substrate on which a metal layer is deposited;
welding the stamp, to which the solar cell layer is attached, to the flexible substrate;
melting the photoresist formed between the solar cell layer and the stamp and the photoresist formed on the side surface of the solar cell layer; and
separating the stamp from the substrate.

2. The method of claim 1, wherein the step of forming the solar cell layer having a predetermined pattern on the substrate comprises steps of:
preparing a substrate comprising a sacrificial layer to pattern the sacrificial layer, thereby forming the solar cell layer and a top electrode on a top surface of the substrate; and
patterning the sacrificial layer so that the patterned sacrificial layer has a surface area greater than that of the solar cell layer.

3. The method of claim 1, further comprising, after the step of patterning the photoresist covering the solar cell layer through the photolithography process, a step of performing an undercut process for selectively removing only the sacrificial layer.

4. The method of claim 1, further comprising, after the step of separating the solar cell layer from the substrate, a step of forming a mask on a lower portion of the solar cell layer to form a bottom electrode on a bottom surface of the solar cell layer.

5. The method of claim 1, wherein, in the step of separating the solar cell layer from the substrate, a top surface and the side surface of the solar cell layer are attached to the stamp and separated from the substrate in a state of being surrounded by the photoresist.

6. The method of claim 5, wherein the solar cell layer is patterned into a plurality of square shapes, and a top electrode having a bar shape is patterned on a top surface of the solar cell layer.

7. The method of claim 1, wherein, in the step of welding the stamp, to which the solar cell layer is attached, to the flexible substrate, the solar cell layer is disposed between the stamp and the flexible substrate, and air remaining between the substrate and the stamp is removed.

8. The method of claim 1, wherein, in the step of melting the photoresist surrounding the solar cell layer, a pressure of 80 kPa and heat having a temperature of 170 degrees are applied to the photoresist to allow the photoresist to cover a top surface and the side surface of the solar cell layer.

9. The method of claim 1, wherein, in the step of melting the photoresist surrounding the solar cell layer, a cold-welding process is performed so that the metal layer disposed on a top surface of the flexible substrate to a bottom surface of the solar cell.

10. The method of claim 1, wherein the stamp comprises a film stamp having a triple structure, which is formed by performing spin coating on one selected from a polyimide (PI) film, polyethylene, polyethylene terephthalate (PET), and polyester by using an elastomeric solution on an elastomeric stamp having adhesion force to adhere again to the other elastomeric stamp.

11. The method of claim 1, further comprising, after the solar cell layer is transferred onto the flexible substrate, a step of forming an electrical connection structure between the solar cell layers.

12. The method of claim 11, wherein the step of forming the electrical connection structure between the solar cell layers comprises steps of:
patterning the metal layer on the flexible substrate to form an electrode pattern;
applying the photoresist to cover the solar cell layer disposed on the flexible substrate;
forming a hole so that portions of the top electrode disposed on the upper portion of the solar cell layer and the electrode pattern disposed on the lower portion of the solar cell layer are exposed; and
forming a metal line to electrically connect the electrode pattern of the adjacent solar cell layer to the top electrode.
